(19) United States
(12) Patent Application Publication
(10) Pub. No.: US 2002/0180007 A1
(43) Pub. Date: Dec. 5, 2002

(54) Semiconductor chip package

(75) Inventor: Yu-Chang Lin, Hsinchu Hsien (TW)

Correspondence Address: Richard P. Berg, Esq., c/o LADAS & PARRY, 5670 Wilshire Boulevard, Suite 2100, Los Angeles, CA, 90036-5679, US

(73) Assignee: Winbond Electronics Corp.

(21) Appl. No.: 10/061,424

(22) Filed: Feb. 1, 2002

(30) Foreign Application Priority Data
May 29, 2001 (TW) 90112893

(51) Int. Cl. H01L 23/495; H01L 23/48; H01L 23/04; H01L 23/52; H01L 29/40

(52) U.S. Cl. 257/666; 257/698; 257/696; 257/784; 257/786

(57) ABSTRACT

A semiconductor chip package comprising a semiconductor chip having peripheral arranged electrode pads, a lead frame comprising a plurality of lead-on-chip leads, standard normal leads and outer leads respectively coupled to the peripheral electrode pads of the semiconductor chip, and a package covering the semiconductor chip and the lead frame.

### BACKGROUND OF THE INVENTION

1. Field of the Invention

The present invention relates in general to a semiconductor chip package. In particular, the present invention relates to an IC using lead-on-chip leads to achieve different designs of semiconductor chips with peripherally arranged electrode pads.

2. Description of the Related Art

FIG. 1 shows a 64 MB semiconductor chip having 32 I/O leads. As shown in FIG. 1, there are 24 electrodes pads 10a and 10b and the leads 21, 22, 23 and 24 connecting with the 24 electrode pads at each of the two short sides of the semiconductor chip 100. The chip 100 is divided into four regions I, II, III and IV. Each region has four random access memories R. Data are input and output through eight electrode pads. This design is no longer in frequent usage.

FIG. 2 shows another 64 MB semiconductor chip having 16 I/O leads. As shown in FIG. 2, there are 24 electrode pads 33a and 33b respectively at each of the two short sides 30 and 31 of the semiconductor chip 200. The chip 200 is divided into four regions I, II, III and IV. Each region has two random access memories R. Data are input and output from the random access memories R in the regions I, II, III and IV via the connection of the 16 electrode pads 33a on the short side 30 with the leads 34. As shown in FIG. 2, after the leads 34 are connected to the off chip driver (OCD) 33a on the semiconductor chip 200, eight input of OCD are connected to a first multiplexer 36a through a first peripheral circuit 35a, and the other eight input of OCD are connected to a second multiplexer 36b through a second peripheral circuit 35b. The first multiplexer 35a is then connected to regions I and III and the second multiplexer is connected to regions II and IV. Nonetheless, the first and the second peripheral circuits 35a and 35b increase the chip die size. Moreover, it takes a significant time delayed for the signal to be transmitted to the four regions I, II, III and IV through the first and second peripheral circuits 35a and 35b.

### SUMMARY OF THE INVENTION

An object of the present invention is to provide a compact semiconductor chip package with higher transmission speeds.

The semiconductor chip package comprises a semiconductor chip having peripherally arranged electrode pads, a lead frame comprising a plurality of lead-on-chip leads, standard normal leads and outer leads respectively coupled to the peripheral electrode pads of the semiconductor chip, and a package covering the semiconductor chip and the lead frame.

The semiconductor chip of the present invention combines both the lead-on-chip leads and the standard normal leads to form a high density semiconductor chip.

### BRIEF DESCRIPTION OF THE DRAWINGS

The present invention can be fully understood by reading the subsequent detailed description in conjunction with the examples and references made to the accompanying drawings, wherein:

FIG. 1 shows a 64 MB semiconductor chip having 32 I/O leads;

FIG. 2 shows another 64 MB semiconductor chip having 16 I/O leads;

FIG. 3 shows a plain view of a semiconductor chip package;

FIG. 4A shows a model of an embodiment of the chip package of the present invention; and

FIG. 4B shows a model of another embodiment of the chip package of the present invention.

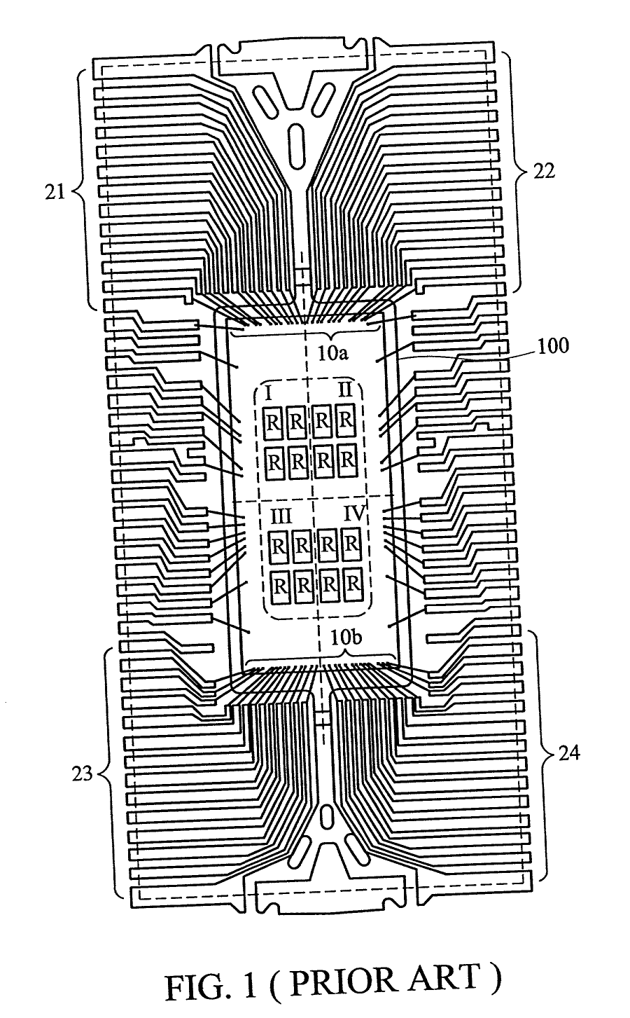

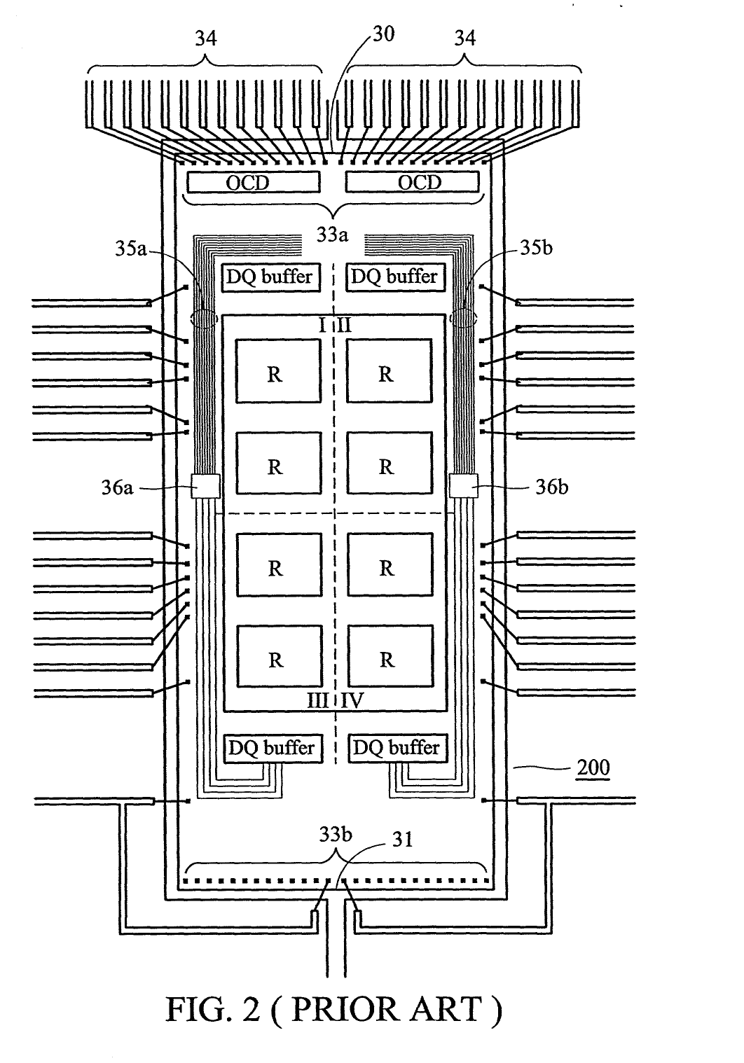

### DETAILED DESCRIPTION OF THE PREFERRED EMBODIMENT

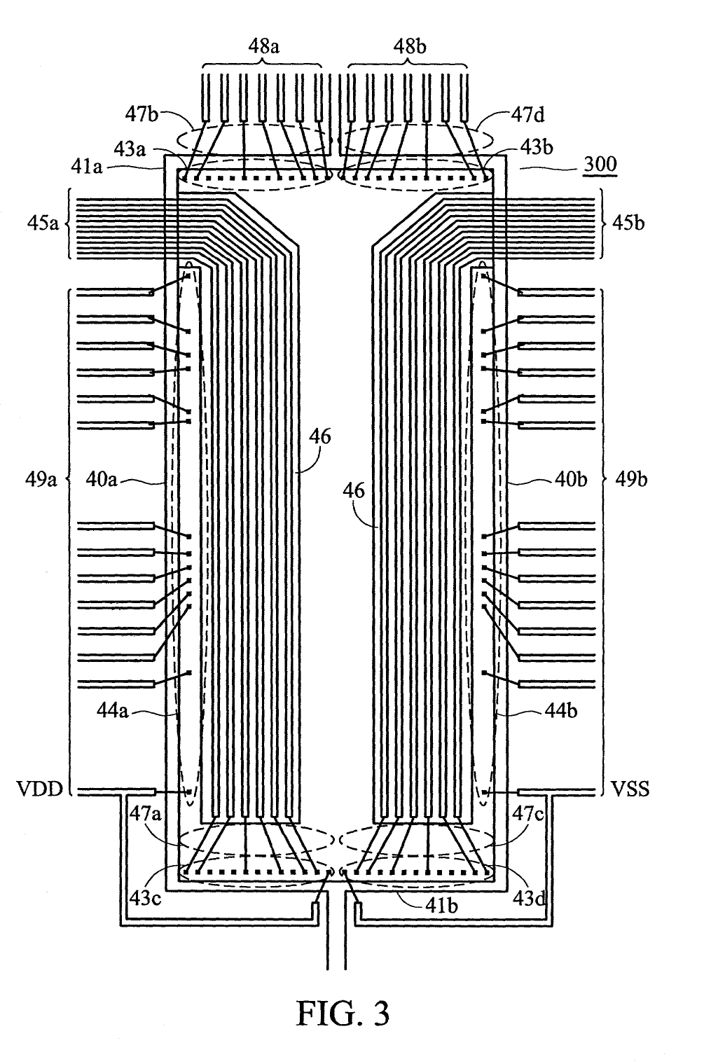

FIG. 3 shows a plain view of a semiconductor chip package. As shown in FIG. 3, the semiconductor chip package comprises 81 I/O pins respectively for transmitting various signals.

The semiconductor chip 300 has two long sides 40a and 40b, two short sides 41a and 41b, and an active surface 42 enclosed by the long and short sides 40a, 40b, 41a, 41b. There are a plurality of circuit components formed on the active surface 42 of the semiconductor chip 300, such as random access memories, control gates, metal lines and a plurality of peripheral arranged electrode pads. The peripheral arranged electrode pads along the long sides 40a and 40b are distributed in electrode pad regions 44a and 44b.

The first lead-on-chip leads 45a are configured along the long side 40a of the chip and are adhered to the bottom of the active surface 42 using an adhesive 46 after bonding. The first lead-on-chip leads 45a are coupled to the electrode pads in the third electrode pad region 43c. The first lead-on-chip leads 45a are further coupled to an outer conductive lead frame (not shown). The adhesive 46 is an electric insulator, such as polyamide acid.

Alternatively, an adhesive tape is utilized to fix the first leads-on-chip leads on the active surface 42 of the chip 300. The first leads-on-chip leads 45a are then pressed under a high temperature against the chip 300, thereby gluing the adhesive tape 46 with the first lead-on-chip leads 45a.

The standard normal leads 48a are configured along the short sides 41a and coupled to the peripherally arranged electrode pads. The first standard normal leads 48a are coupled to the first electrode pad region 43a through conductive lines 47b. The first standard normal leads 48a can be coupled to outer leads (not shown).

According to the method described, the second lead-on-chip leads 45b are configured along the other long side 40b of the chip 300 and adhered to the bottom of the active surface 42 with the adhesive 46. The second lead-on-chip leads 45b are coupled to the forth electrode pad region 43d through conductive lines 47c. The second standard normal leads 48b are configured along the short sides 41a on the peripherally arranged electrode pads. The second standard normal leads 48b are coupled to the second electrode pad region 43b through conductive lines 47d. The first standard normal leads 48b can be coupled to outer leads (not shown).

The semiconductor chip having the structure combining the lead-on-chip leads and the standard normal leads overcomes the limit on lead frames so that packing of the high density memories becomes more efficient. The lead-on-chip leads prevent signal distortion and enhance the signal transmission rate.

VDD and VSS are power leads providing steady power voltage to the semiconductor chip 300. The electrode pads regions 40a and 40b coupled with the standard normal leads 49a and 49b are generally associated with the control port and address port. The standard normal leads 49a and 49b are coupled to a plurality of outer leads (not shown in the graph).

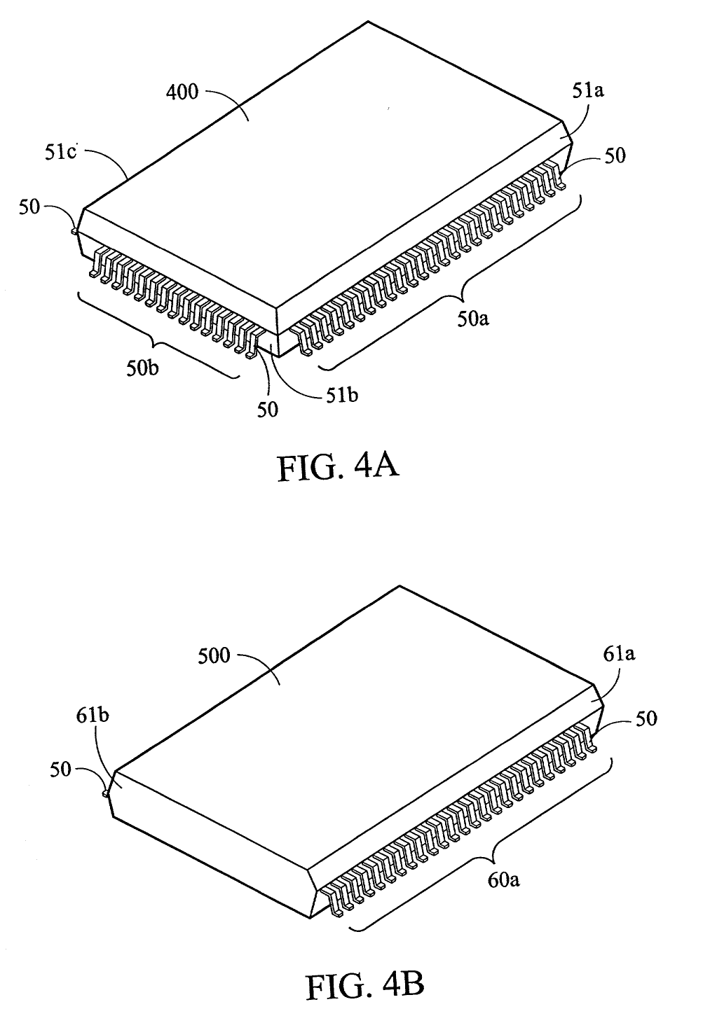

FIG. 4A shows a model of an embodiment of the chip package of the present invention. The semiconductor chip 400 is a three-side package. Outer leads 50 protrudes along the three sides 51a, 51b and 51c of the package. The outer leads 50 are shaped to simulate the letter “J” or a gullwing to electrically connect a circuit board (not shown in the graph).

As shown in FIGS. 3 and 4A, the three-side package 400 electrically couples the first and second standard normal leads 48a and 48b with the outer leads 50 along the short side 41a of the chip 300. The outer leads 50 then protrude from the short side 51b of the package 400.

FIG. 4B shows a model of yet another embodiment of the chip package of the present invention. The semiconductor chip 500 is a two-side package. An outer leads 50 protrudes along the two sides 61a, 61b of the package. The outer leads 50 are shaped to simulate the letter “J” or a sea gull wing to electrically connect a circuit board (not shown in the graph). Referring to FIGS. 3 and 4B, the two-side package 500 electrically couples the first and second standard normal leads 48a and 48b with the outer leads 50 along the short side 41a of the chip 300. The outer leads 50 then protrudes the short side 51b of the package 400.

Finally, while the invention has been described by way of example and in terms of the preferred embodiment, it is to be understood that the invention is not limited to the disclosed embodiments. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A semiconductor chip package comprising:
a semiconductor chip, comprising a first pair of opposite sides, a second pair of opposite sides, an active surface and a plurality of peripherally arranged electrode pads, wherein the plurality of peripherally arranged electrode pads are located along the first pair of opposite sides and the second pair of opposite sides;
a lead frame, comprising a plurality of lead-on-chip leads, standard normal leads and outer leads, wherein the plurality of lead-on-chip leads are coupled to the plurality of electrode pads on one of the first pair of opposite sides, and the plurality of standard normal leads are coupled to the electrode pads on the second pair of opposite sides and the other of the first pair of opposite sides, and the outer leads are respectively coupled to the plurality of lead-on-chip leads and the standard normal leads; and
a package, covering the semiconductor chip and the lead frame.

2. The semiconductor chip package in claim 1, wherein the lead-on-chip leads are adhered to the active surface using tape.

3. The semiconductor chip package in claim 1, wherein the lead-on-chip leads are adhered to the active surface using an adhesive.

4. The semiconductor chip package in claim 1, wherein the lead-on-chip leads are configured along the second pair of opposite sides of the chip and are coupled to the plurality of electrode pads on one of the first pair of opposite sides after bending.

5. The semiconductor chip package in claim 1 further comprises a plurality of sides, wherein the outer leads protrude along three of the sides to form a three-side semiconductor chip package.

6. The semiconductor chip package in claim 1 further comprises a plurality of sides, wherein the outer leads protrude along two of the sides to form a two-side semiconductor chip package.
